(19) United States
(12) Patent Application Publication
(10) Pub. No.: US 2026/0344397 A1
(43) Pub. Date: Oct. 29, 2026

(54) CRUCIFORM BONDING STRUCTURE FOR 3D-IC

(71) Applicant: Taiwan Semiconductor Manufacturing Company, Ltd., Hsinchu (TW)

(72) Inventors: Hao-Lin Yang, Kaohsiung City (TW); Kuan-Chieh Huang, Hsinchu City (TW); Wei-Cheng Hsu, Kaohsiung City (TW); Tzu-Jui Wang, Fengshan City (TW); Ching-Chun Wang, Tainan (TW); Hsiao-Hui Tseng, Tainan City (TW); Chen-Jong Wang, Hsin-Chu (TW); Dun-Nian Yaung, Taipei City (TW)

(21) Appl. No.: 19/732,734

(22) Filed: Jul. 7, 2026

Related U.S. Application Data
(62) Division of application No. 18/149,789, filed on Jan. 4, 2023.
(60) Provisional application No. 63/415,406, filed on Oct. 12, 2022.

(51) Int. Cl. H10W 20/42; H10W 72/00; H10W 72/90; H10W 80/00; H10W 90/00

(52) U.S. Cl. CPC H10W 20/42; H10W 90/00; H10W 72/019; H10W 72/926; H10W 72/932; H10W 72/9415; H10W 80/721; H10W 80/732; H10W 80/743; H10W 90/792

(57) ABSTRACT

A bonding structure that may be used to form 3D-IC devices is formed using first oblong bonding pads on a first substrate and second oblong bonding pads one a second substrate. The first and second oblong bonding pads are laid crosswise, and the bond is formed. Viewed in a first cross-section, the first bonding pad is wider than the second bonding pad. Viewed in a second cross-section at a right angle to the first, the second bonding pad is wider than the first bonding pad. Making the bonding pads oblong and angling them relative to one another reduces variations in bonding area due to shifts in alignment between the first substrate and the second substrate. The oblong shape in a suitable orientation may also be used to reduce capacitive coupling between one of the bonding pads and nearby wires.

### REFERENCE TO RELATED APPLICATIONS

This Application is a Divisional of U.S. application Ser. No. 18/149,789, filed on Jan. 4, 2023, which claims the benefit of U.S. Provisional Application No. 63/415,406, filed on Oct. 12, 2022. The contents of the above-referenced Patent Applications are hereby incorporated by reference in their entirety.

### BACKGROUND

3D packaging provides a pathway to meeting the demands for next generation devices. 3D packages include integrated fan-out (InFO) packages, chip on wafer on substrate packages, and wafer on wafer packages. In each case the packaging process includes bonding to form electrical connections between two substrates. Forming the bonds using metal inlays as opposed to solder bumps allows the formation of high density bonds and is a particularly useful approach for applications such as complementary metal oxide semiconductor (CMOS) image sensors, memory devices, and system-on-chip (SoC) devices. The metal inlays form bonds and provide electrical connections at a bonding interface. Dielectric to dielectric bonds may also be formed at the bonding interface in order to provide supplemental adhesion. The bonds are formed by aligning and fusing the two substrates at the bonding interface.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B illustrate cross-sectional side views of a three-dimensional integrated circuit (3D-IC) device with bonding structures in accordance with some embodiments of the present disclosure. These two cross-sectional side views are at right angles to one another.

FIG. 2A illustrates an alignment of two bonding pads in accordance with an embodiment of the present disclosure.

FIGS. 2B-2I illustrate variations on the alignment of FIG. 2A, which variations constitute additional embodiments of the present disclosure.

FIG. 3A illustrates an alignment of two bonding pads in accordance with an embodiment of the present disclosure.

FIGS. 3B-3I illustrate variations on the alignment of FIG. 3A, which variations constitute additional embodiments of the present disclosure.

FIG. 4A illustrates an alignment of two bonding pads in accordance with an embodiment of the present disclosure.

FIGS. 4B-4I illustrate variations on the alignment of FIG. 4A, which variations constitute additional embodiments of the present disclosure.

FIG. 5A illustrates an alignment of two bonding pads in accordance with an embodiment of the present disclosure.

FIGS. 5B-5I illustrate variations on the alignment of FIG. 5A, which variations constitute additional embodiments of the present disclosure.

FIG. 6 provides a diagram for a circuit in accordance with some embodiments of the present disclosure.

FIG. 7A provides a cross-sectional view of a first integrated circuit (IC) device with a bonding pad in accordance with some embodiments of the present disclosure.

FIG. 7B provides a plan view taken along the line 7B-7B′ of FIG. 7A.

FIG. 7C provides a plan view taken along the line 7C-7C′ of FIG. 7A.

FIG. 8A provides a cross-sectional view of a second IC device with a bonding pad in accordance with some embodiments of the present disclosure.

FIG. 8B provides a plan view taken along the line 8B-8B′ of FIG. 8A.

FIG. 8C provides a plan view taken along the line 8C-8C′ of FIG. 8A.

FIG. 9 provides a diagram for a circuit in accordance with some other embodiments of the present disclosure.

FIG. 10 illustrates a cross-sectional side view of another 3D-IC device with a bonding structure in accordance with some embodiments of the present disclosure.

FIGS. 11-25 illustrate a process of forming a 3D-IC device with bonding structures in accordance with some embodiments to the present disclosure. FIGS. 11-14 and 16-25 illustrate cross-sectional views. FIGS. 15A and 15B are plan views taken along the lines 15A-15A′ and 15B-15B′ of FIG. 14.

FIG. 26 provides a flow chart illustrating a method of forming a 3D-IC device in accordance with some embodiments of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some aspects of the present disclosure relate to a bonding structure in which bonding pad surfaces are oblong and angled relative to one another. In some embodiments, the bonding pad surfaces are laid crosswise. Making the bonding pad surfaces oblong and angling them relative to one another reduces variations in bonding area due to shifts in alignment between the first substrate and the second substrate. For example, if the bonding pad surfaces are 0.25 μm by 0.64 μm rectangles laid crosswise the alignment may vary by 0.195 μm in any direction without causing a change in the contact area (0.0625 μm²). Square bonding pad surfaces with an equivalent area (0.4 μm per side) subject to the same variation in alignment will have contact area in the range from 0.0687 μm² to 0.16 μm². The mating crosswise rectangular bond pad surfaces substantially maintain the minimum contact area while eliminating large variations in contact area due to variation in alignment within a given magnitude. In some embodiments the bonding pad surfaces are elliptical. An elliptical shape may be easiest to manufacture. In some embodiments, the shapes and orientations of the bonding pad surfaces limit an area of contact between the bonding pad surfaces to about one tenth to about three quarters the area of the smallest of the two bonding pad surfaces. In some embodiments, the maximum area of contact is within the range from about one fourth to about two thirds the area of the smallest of the two bonding pad surfaces. The bonding pad surfaces may have any oblong shapes that have a length greater than a width. In some embodiments the bonding pad surfaces are rectangular. A rectangular shape may provide the most efficient area utilization.

Some aspects of the present disclosure relate to a three-dimensional integrated circuit (3D-IC) device that includes a first bonding pad on a first IC device and a second bonding pad on a second IC device. The first bonding pad is bonded to the second bonding pad at a bonding interface that is formed between the first IC device and the second IC device. Viewed in a first cross-section, the first bonding pad is wider than the second bonding pad. Viewed in a second cross-section at a right angle to the first, the second bonding pad is wider than the first bonding pad. The first bonding pad may be one in an array on the first IC device and the second bonding pad may be one in an array of mating bonding pads on the second IC device. In some embodiments, the arrays are two-dimensional arrays. In some embodiments, the first bonding pads correspond with photodetectors in an array comprising photodiodes on the first IC device. In some embodiments, reset transistors, select transistors, or source follower transistors associated with the photodetectors in the array are located on the second IC device. The bond structure of the present disclosure provides high yield and consistent performance in the photodetector application and in other applications in which a high density of bonding pads is sought after.

In some embodiments the bonding pads on one of the IC devices are formed above a metal interconnect. In some embodiments two wires in the metal interconnect run parallel to a length of one of the bonding pads. The two wires are in a metallization layer immediately below the bonding pad and are the wires closest to the bonding pad among those in the metallization layer and not coupled to the bonding pad. Keeping the longer direction of the bonding pad parallel to the wires reduces the distance between the bonding pad and the wires and thereby reduces capacitive coupling. In some embodiments the bonding pads of both IC devices are formed above metal interconnects. In some embodiments, three substrates in a vertical stack are bonded together with bonding structures in accordance with the present disclosure.

Some aspects of the present disclosure relate to a method of forming a bonding structure. The method includes forming bonding pads with oblong bonding pad surfaces on each of two substrates. The bonding pads are inlaid within dielectrics. The bonding pad surfaces are aligned crosswise and then joined together. In some embodiments, the joining process includes annealing.

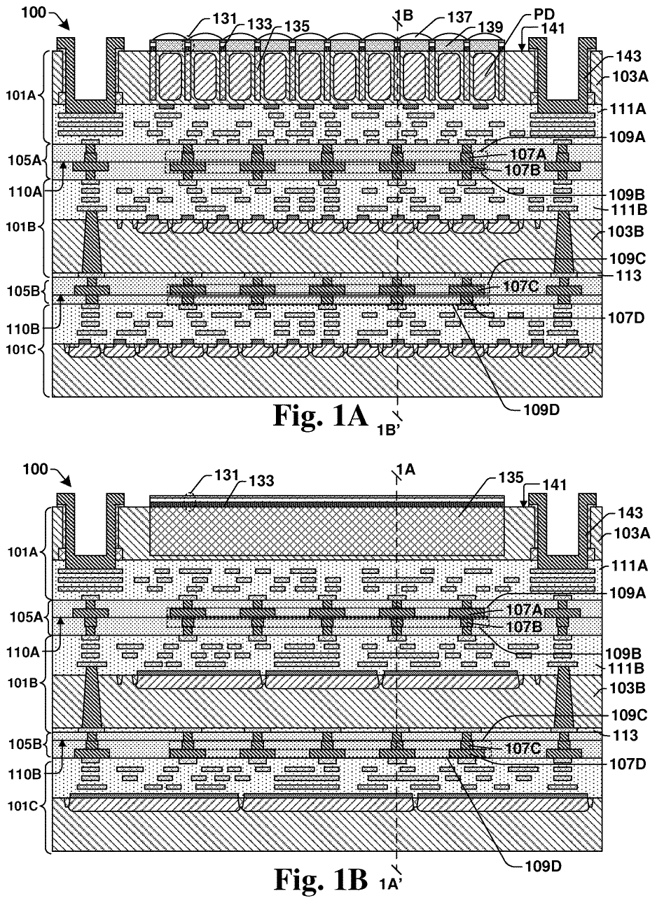

FIG. 1A illustrates a first cross-sectional view of a 3D-IC device 100 comprising a first IC device 101A, a second IC device 101B, and a third IC device 101C connected by a first bonding structure 105A and a second bonding structure 105B, which are bonding structures in accordance with some embodiments of the present disclosure. FIG. 1B illustrates a second cross-sectional view of the 3D-IC device 100 which is at a right angle to the first cross-sectional view. The second cross-sectional view of FIG. 1B corresponds to the line 1B-1B′ of FIG. 1A. The first cross-sectional view of FIG. 1A corresponds to the line 1A-1A′ of FIG. 1B.

The first bonding structure 105A includes an array 109A of bonding pads 107A on the first IC device 101A. The bonding pads 107A are bonded to corresponding bonding pads 107B in an array 109B on the second IC device 101B along a bonding interface 110A. Within the first cross-sectional view of FIG. 1A the bonding pads 107B are wider than the bonding pads 107A. Within the second cross-sectional view of FIG. 1B the bonding pads 107A are wider than the bonding pads 107B. The appearances of the bonding pads 107A and the bonding pads 107B as shown in the cross-sectional views FIGS. 1A and 1B and the relationships between their widths are the same for corresponding cutaway side views that show the bonding pads 107A and the bonding pads 107B in their entireties.

The cross-sections of the bonding pads 107B are the bonding pads 107A are shown as rectangular but they may be trapezoidal due to the etch processes used in forming inlays. The variation in shape with respect to depth that result from these trapezoidal structures is not significant. To the extent that a bonding pad has a significant variation in shape with respect to depth, the shape that is most relevant to the present disclosure is the shape at the surface where bonding takes place, e.g., at the bonding interface 110A or the bonding interface 110B.

The second bonding structure 105B includes an array 109C of bonding pads 107C on the second IC device 101B. The bonding pads 107C are bonded to corresponding bonding pads 107D in an array 109D on the third IC device 101C along a bonding interface 110B. Within the first cross-sectional view of FIG. 1A the bonding pads 107D are wider than the bonding pads 107C. Within the second cross-sectional view of FIG. 1B the bonding pads 107C are wider than the bonding pads 107D. In the following description various options are given for the bonding pads 107A, the bonding pads 107B, and their geometric relationships. The same description applies to the bonding pads 107C and the bonding pads 107D.

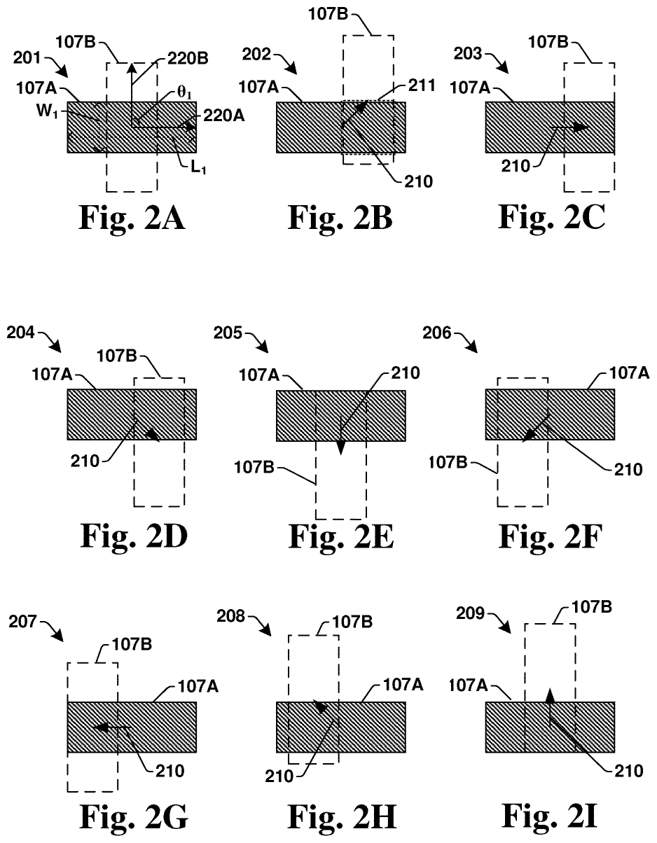

FIG. 2A illustrates a plan view 201 in accordance with some embodiments of the present disclosure showing one of the bonding pads 107A and one of the bonding pads 107B. The bonding pad 107A lays across the bonding pad 107B. In the plan view 201, the bonding pad 107A and the bonding pad 107B have the same length and width, are at right angles to one another, and are centered with respect to one another. The bonding pads 107A and 107B have rectangular surfaces. They are oblong in that they have a length L₁ that is greater than a width W₁. In some embodiments, the bonding pads 107A and the bonding pads 107B have the same length and width. It will be appreciated, however, that the bonding pads 107A and the bonding pads 107B may have different lengths and widths.

FIGS. 2B-2I show plan views 202-209, which are variations obtained by linearly displacing the bonding pad 107B from its position in the plan view 201 of FIG. 2A by a displacement distance 210 in one of eight ordinal directions in the plane of the bonding interface 110A (see FIG. 1A). As shown by these views, a contact area 211 between the bonding pad 107A and the bonding pad 107B remains constant for linear displacements less than or equal to the displacement distance 210. For the alignment illustrated by the plan view 201 of FIG. 2A, the derivative of the contact area 211 with respect to linear displacements in the plane of the bonding interface 110A (the rate of bonding area variation with respect to linear variations in alignment) is zero.

The displacement distance 210 equals 0.5 (L₁−W₁). The area of contact area 211 equals W₁ squared for any of the alignments shown in the plan views 201-209. For a constant bonding pad area, increasing the ratio of L₁ to W₁ reduces the contact area 211 in the case of ideal alignment but increases the displacement distance 210 over which the contact area 211 remains constant. In some embodiments, the length L₁ is in the range from about 1.2 and to about 10 times the width W₁. In some embodiments, the length L₁ is in the range from about 1.5 to about 3 times the width W₁. If the ratio is too small, the sensitivity to misalignment may be too high. If the ratio is too large, the contact area 211 may be too small.

The bonding pad 107A may have any suitable oblong shape. For a bonding pad with a rectangular surface, the length L₁ and the width W₁ are conventionally defined. For a bonding pad with an elliptical surface, the length L₁ is the length of the major axis and the width W₁ is the length of the minor axis. The width may be defined as the shortest line of mirror symmetry on the bonding pad surface and the length may be the longest line of mirror symmetry. For shapes lacking one of these lines of mirror symmetry, the length and the width may be defined as those of the smallest rectangle that fits around the bonding pad surface. A bonding pad may be considered oriented along a direction of its length with an orientation vector positioned on its center line.

The bonding pads 107A and 107B are twisted with respect to one another so that their respective orientation vectors 220A and 220B are nonparallel. This twisting allows the bonding pad 107A to lay across the bonding pad 107B. In some embodiments, the orientation vectors 220A and 220B form an angle θ₁ that is at least about 45 degrees. In some embodiments, the angle θ₁ is at least about 60 degrees. In some embodiments, the angle θ₁ is about 90 degrees. Having the bonding pad 107A and the bonding pad 107B lay across one another at right angles provides the greatest benefit.

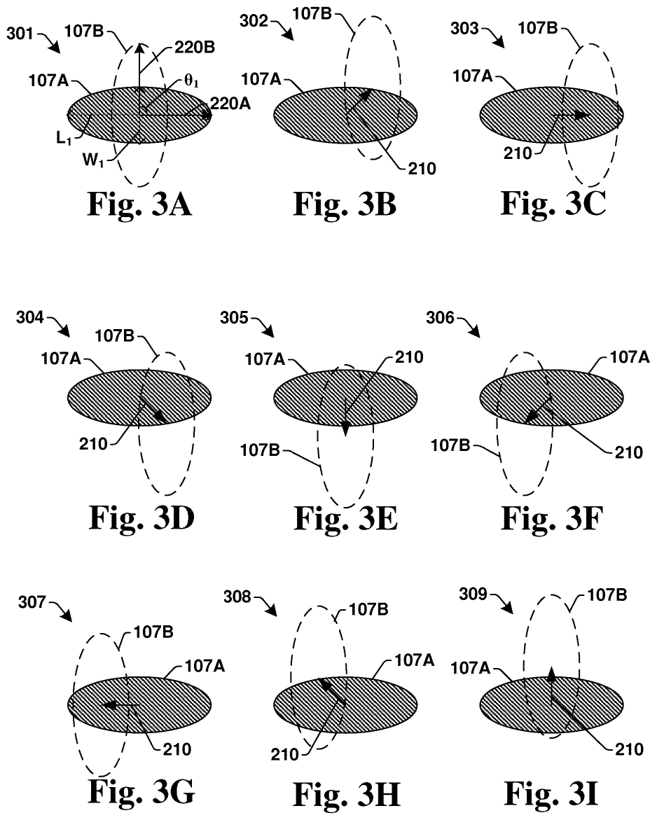

FIG. 3A illustrates a plan view 301 of the bonding pad 107A and the bonding pad 107B in accordance with some other embodiments of the present disclosure. In the plan view 301, the bonding pad 107A and the bonding pad 107B have elliptical surfaces, are at right angles to one another, and are centered with respect to one another. They are oblong in that they have a length L₁ that is greater than a width W₁.

FIGS. 3B-3I show plan views 302-309, which are variations obtained by linearly displacing the bonding pad 107B from its position in the plan view 301 of FIG. 3A by the displacement distance 210 in one of eight ordinal directions. As shown by these views, a contact area between the bonding pad 107A and the bonding pad 107B varies slightly with respect to linear displacements from the position shown in the plan view 301 of FIG. 3B, however, the variations are much smaller than for round or rectangular bonding pad ayrfaces of equivalent area.

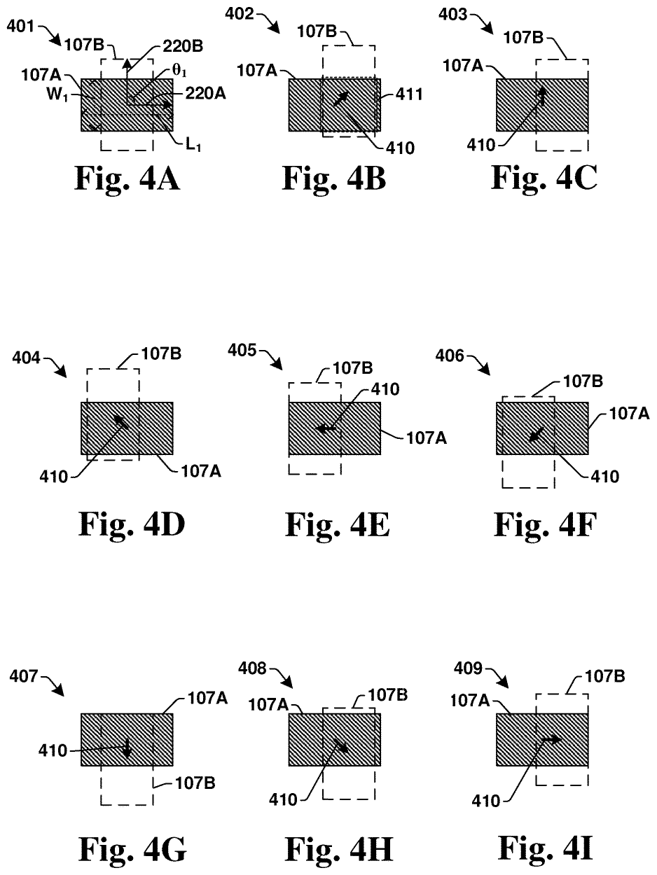

FIG. 4A illustrates a plan view 401 of the bonding pad 107A and the bonding pad 107B in accordance with some other embodiments of the present disclosure. The plan view 401 is similar to the plan view 201 except that in the plan view 401 the ratio of L₁ to W₁ is smaller. In the plan view 401, the ratio of L₁ to W₁ is 1.76:1. For example, L₁ may be 0.44 μm while W₁ is 0.25 μm. In the plan view 201, the ratio of L₁ to W₁ is 2.56:1. For example, L₁ may be 0.64 μm while W₁ is 0.25 μm

FIGS. 4B-4I show plan views 402-409, which are variations obtained by linearly displacing the bonding pad 107B from its position in the plan view 401 of FIG. 4A by the displacement distance 410 in one of eight ordinal directions. The displacement distance 410 is the maximum for which there is no change in the contact area 411 (see FIG. 4B) regardless of the direction of the displacement. The displacement distance 410 may be 0.095 μm for the case where L₁ is 0.44 μm and W₁ is 0.25 μm. For a square bonding pad surfaces of equivalent area, the displacement distance 410 may reduce the contact area up to 36%. For the alignment variations represented by FIGS. 4B-4I, making the bonding pad surfaces rectangular rather than square eliminates contact area variations.

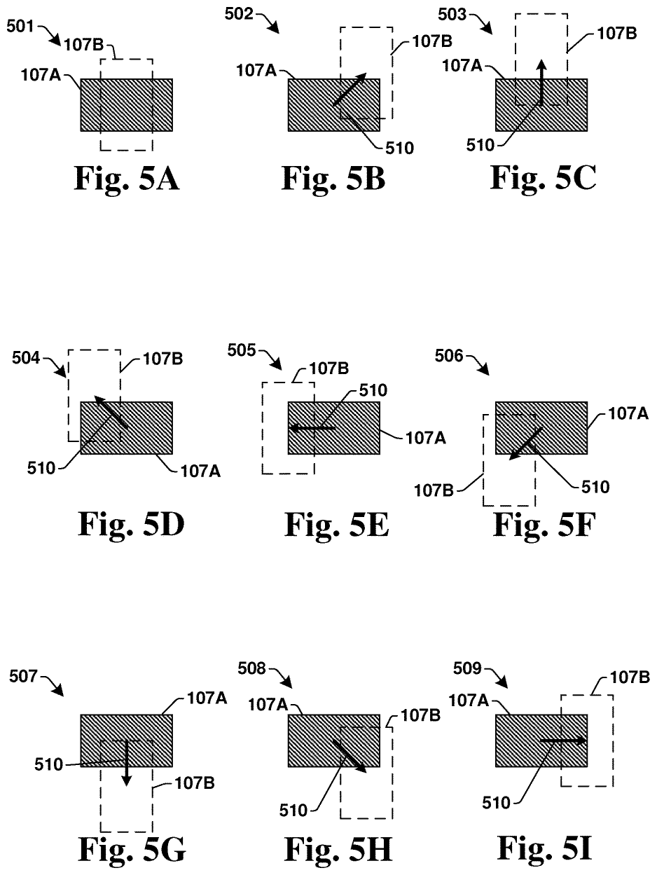

FIG. 5A illustrates a plan view 501 of the bonding pad 107A and the bonding pad 107B. The plan view 501 is the same as the plan view 401 of FIG. 4A. FIGS. 5B-5I show plan views 502-509, which are variations obtained by linearly displacing the bonding pad 107B from its position in the plan view 501 of FIG. 5A by the displacement distance 510 in one of eight ordinal directions. The displacement distance 510 is such that the reduction in contact area 511 is up to 50%, e.g., 0.22 μm for the case where L₁ is 0.44 μm and W₁ is 0.25 μm. For square bonding pad surfaces of equivalent area, the displacement distance 510 would reduce the contact area up to 78%. For the alignment variations represented by FIGS. 5B-5I, making the bonding pad surfaces rectangular rather than square both reduces bonding area variations and increases the minimum contact area.

Referring again to FIG. 1A, in some embodiments the bonding pads 107A and 107B have pitches in the range from about 0.1 μm to about 2 μm within the arrays 109A and 109B respectively. In some embodiments, the pitches are in the range from about 0.3 μm to about 0.9 μm. If the pitches are too high, bonding pad density is limited. If the pitches are too low, manufacturing may be impractical or result in low yields. In some embodiments, the arrays 109A and 109B are two-dimensional arrays. The arrays 109A and 109B may be formed over metal interconnects 111A and 111B.

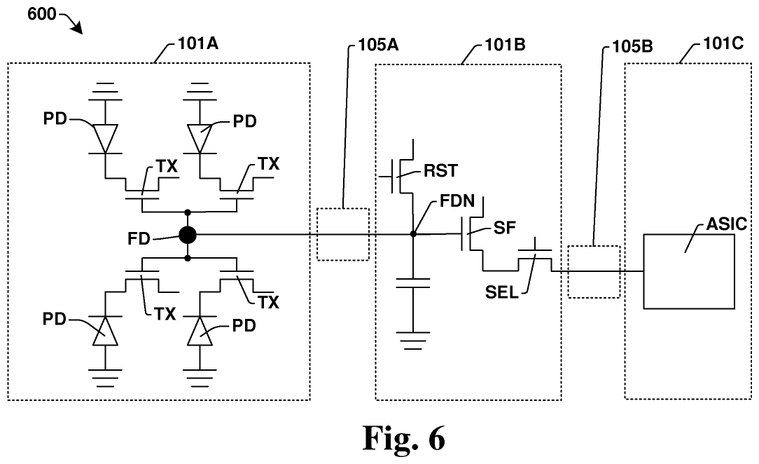

FIG. 6 provides a diagram for a circuit 600 that may be implemented in the 3D-IC device 100 of FIGS. 1A and 1B. The circuit 600 includes photodiodes PD, transfer gates TX, and a floating diffusion region FD on the first IC device 101A, a reset transistor RST, a source follower SF, and a select transistor SEL on the second IC device 101B, and an application specific integrated circuit ASIC on the third IC device 101C. The floating diffusion region FD on the first IC device 101A is coupled to a floating diffusion node FDN on the second IC device 101B through the first bonding structure 105A. A drain of the source follower transistor SF on the second IC device 101B is coupled to the application specific integrated circuit ASIC on the third IC device 101C through the second bonding structure 105B.

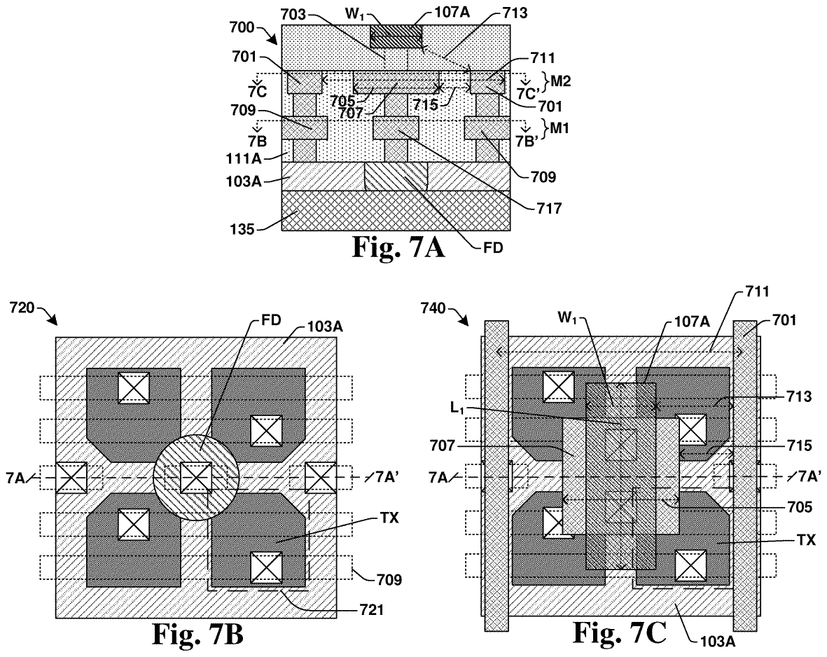

FIGS. 7A-7C illustrate an implementation of the circuit 600 on the first IC device 101A including some details of the metal interconnect 111A which is shown only schematically in FIGS. 1A and 1B. In this example the metal interconnect 111A includes a metallization layer M1 and metallization layer M2. FIG. 7A provides a cross-sectional view 700. FIG. 7B is a plan view 720 along the line 7B-7B′ of FIG. 7A. FIG. 7C is a plan view 740 along the line 7C-7C′ of FIG. 7A. FIG. 7A corresponds to the line 7A-7A′ in FIGS. 7B and 7C. In FIGS. 7B and 7C, structures of the metallization layer M1 are shown in outline.

As shown in FIG. 7A, the floating diffusion region FD may be formed in the substrate 103A and have an opposite doping type from a bulk of the substrate 103A. The floating diffusion region FD is coupled to the bonding pad 107A through a metal island 717 in the metallization layer M1 and a metal island 707 in the metallization layer M2. The metal island 707 may be enlarged to increase a capacity of the floating diffusion region FD.

The floating diffusion region FD may be directly over a back side isolation structure 135 and is coupled to photodiodes PD (see FIGS. 1A and 1B) of photodetectors 721 through transfer gates TX. The transfer gates TX are coupled to wires 709 in the metallization layer M1. Ground wires 701 disposed in the metallization layer M2 are coupled to the substrate 103A. The length L₁ of the bonding pad 107A may be oriented parallel to the ground wires 701 so that a distance 713 between the bonding pad 107A and the ground wires 701 is greater than or equal to a distance 715 between the metal island 707 and the bonding pad 107A. For example, a pitch 711 of the ground wires 701 may be about 0.89 μm, a width 705 of the metal island 707 may be about 0.45 μm and the distance 715 may be about 0.17 μm. If the length L₁ is 0.64 μm and the width W₁ is 0.25 μm, orienting the bonding pad 107A parallel to the ground wires 701 keeps the bonding pad 107A further from the ground wires 701 than is the metal island 707.

In some embodiments, the first bonding structure 105A (see FIG. 1A) includes a contact layer with vias 703 (see FIG. 7A) that couples the bonding pads 107A to an underlying metallization layer, e.g., the metallization layer M2. In some embodiments, the contact layer is omitted and the bonding pads 107A are placed in direct contact with the metal island 707 or some other structure in the underlying metallization layer.

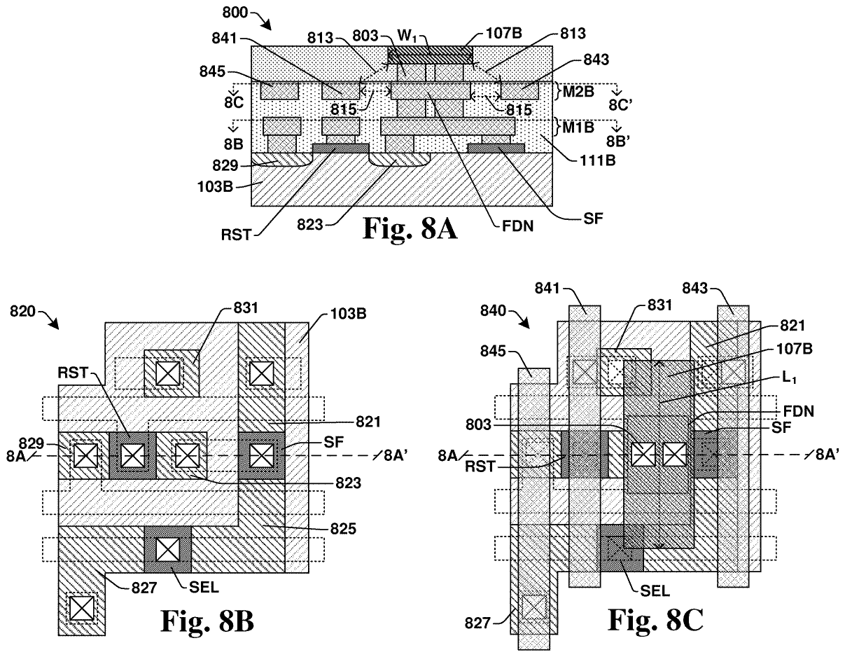

FIGS. 8A-8C illustrate an implementation of the circuit 600 on the second IC device 101B including some details of the metal interconnect 111B, which is shown only schematically in FIGS. 1A and 1B. In this example the metal interconnect 111B includes a metallization layer M1B and metallization layer M2B. FIG. 8A provides a cross-sectional view 800. FIG. 8B is a plan view 820 along the line 8B-8B′ of FIG. 8A. FIG. 8C is a plan view 840 along the line 8C-8C′ of FIG. 8A. FIG. 8A corresponds to the line 8A-8A′ in FIGS. 8B and 8C. In FIGS. 8B and 8C, the metallization layer M1B is shown in outline.

As shown in FIG. 8B, structures formed in the substrate 103B include a bulk contact 831, a reset transistor drain region 829, a reset transistor source region 823, a source follower drain region 821, a source follower source region/select transistor drain region 825, and a select transistor source region 827. As shown in FIG. 8C, a select gate source line 845 in the metallization layer M2B is coupled to the select transistor source region 827. A ground line 841 in the metallization layer M2B is coupled to the bulk contact 831. A source follower drain line 843 in the metallization layer M2B is coupled to the source follower drain region 821. The floating diffusion node FDN in the metallization layer M2B is coupled to the bonding pad 108B, the source follower SF, and the reset transistor source region 823.

The ground line 841 and the source follower drain line 843 are the closest to the bonding pad 107B among the wires in the metallization layer M2B that are not coupled bonding pad 107B. The length L₁ of the bonding pad 107B may be oriented parallel to the ground line 841 and the source follower drain line 843 so that a distance 813 between the bonding pad 107B and these wires is greater than or equal to a distance 815 between the floating diffusion node FDN and these wires.

In some embodiments, the first bonding structure 105A (see FIG. 1A) includes a layer with vias 803 (see FIG. 8B) that couples the bonding pads 107B to wires in an underlying metallization layer, e.g., the floating diffusion node FDN. In some embodiments, this layer is omitted and the bonding pads 107B are placed in direct contact with the floating diffusion node FDN or other structures in the underlying metallization layer.

With reference to the 3D-IC device 100 of FIG. 1A and the circuit 600 of FIG. 6, in some embodiments the number of bonding pads 107A is within an order of magnitude of the number of devices on the substrate 103A. In some embodiments, the photodiodes PD and transfer gates TX comprise a majority of the devices on the substrate 103A. In some embodiments, there is one bonding pad 107A for every four photodiodes PD. In some embodiments there is one bonding pad 107A for every two photodiodes PD. In some embodiments there is one bonding pad 107A for every photodiode PD.

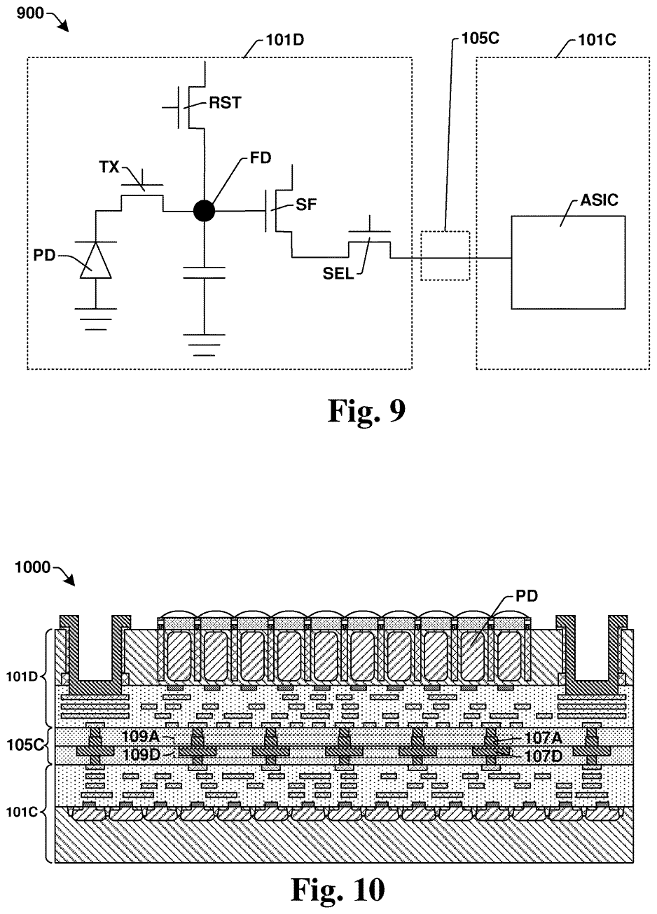

FIG. 9 provides a diagram for a circuit 900 in which there is one bonding pad 107A for every photodiode PD. FIG. 10 illustrates a cross-sectional view of a 3D-IC device 1000 that may implement the circuit 900. All the photodetector components including the photodiode PD, the transfer gate TX, the floating diffusion region FD, the reset transistor RST, the source follower SF, and the select transistor SEL, are on a fourth IC device 101D. The fourth IC device 101D is coupled to the third IC device 101C through a third bonding structure 105C. Rather than photodetectors, the fourth IC device 101D may provide memory cells, logic devices, a combination thereof, or any other types of semiconductor devices.

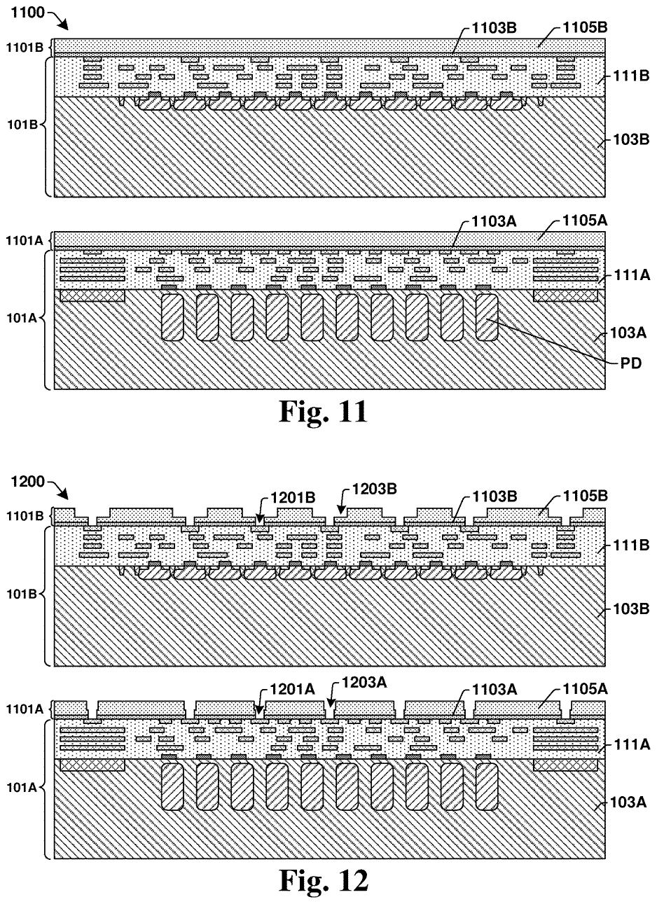

FIGS. 11 through 25 provide illustrations exemplifying a method of the present disclosure of forming a 3D-IC with bonding structures according to some embodiments. While FIGS. 11 through 25 are described with reference to various embodiments of a method, it will be appreciated that the structures shown in FIGS. 11 through 25 are not limited to the method but rather may stand alone separate from the method. FIGS. 11 through 25 are described as a series of acts. The order of these acts may be altered in other embodiments. While FIGS. 11 through 25 illustrate and describe a specific set of acts, some may be omitted in other embodiments. Further, acts that are not illustrated and/or described may be included in other embodiments. While the method of FIGS. 11 through 25 is described in terms of forming the 3D-IC device 100, the method may be used to form other 3D-IC devices.

As shown by the cross-sectional view 1100 of FIG. 11, the method may begin with forming a dielectric bonding structure 1101B over the metal interconnect 111B of the second IC device 101B and a dielectric bonding structure 1101A over the metal interconnect 111A of the first IC device 101A. The dielectric bonding structure 1101A includes one or more layers of suitable dielectrics. In some embodiments, the dielectric bonding structure 1101A includes a bonding pad etch stop layer 1103A and a bonding pad interlevel dielectric (ILD) layer 1105A. Likewise, the dielectric bonding structure 1101B may include a bonding pad etch stop layer 1103B and a bonding pad ILD layer 1105B. The bonding pad etch stop layers 1103A and 1103B may be or comprise, for example, a nitride such as silicon nitride (SiN) or silicon oxynitride (SiON), a carbide such as silicon carbide (SiC) or silicon oxycarbide (SiOC), or the like. In some embodiments the bonding pad ILD layers 1105A and 1105B are or comprise silicon dioxide (SiO₂), carbon doped silicon dioxide, silicon nitride (SiN), silicon oxynitride (SiON), borosilicate glass (BSG), phosphoric silicate glass (PSG), borophosphosilicate glass (BPSG), fluorinated silicate glass (FSG), a low-κ dielectric, a porous dielectric, a combination thereof, or the like. In some embodiments the bonding pad ILD layers 1105A and 1105B comprise a polymer. Examples of polymers that may be used include benzocyclobutene (BCB) polymer, polyimide (PI), polybenzoxazole (PBO), and the like. The bonding pad etch stop layers 1103A and 1103B and the bonding pad ILD layers 1105A and 1105B layers may be deposited by physical vapor deposition (PVD), chemical vapor deposition (CVD), atomic layer deposition (ALD), spin coating, a combination thereof, the like, or any other suitable process.

As shown by the cross-sectional view 1200 of FIG. 12, bonding pad openings 1203A and via openings 1201A may be formed in the dielectric bonding structure 1101A and bonding pad openings 1203B and via openings 1201B may be formed in the dielectric bonding structure 1101B. The processes of forming these openings may include photolithography and etching of the type used in damascene or dual damascene processes.

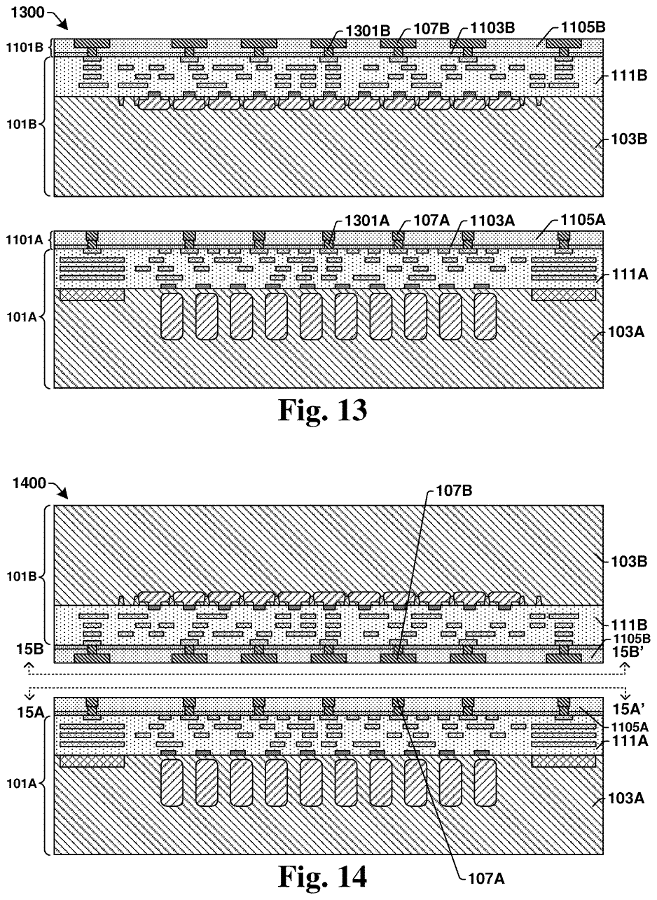

As shown by the cross-sectional view 1300 of FIG. 13, the bonding pad openings 1203A and 1203B and the via openings 1201A and 1201B may be filled with metals or other suitable conductors to form the bonding pads 107A and 107B and the vias 1301A and 1301B. The metal may be or comprise, for example, copper (Cu), nickel (Ni), aluminum (Al), tungsten (W), a combination thereof, or the like. In some embodiments the metal comprises copper (Cu). A diffusion barrier layer may be deposited before the metal. The diffusion barrier layer may be, for example, silicon nitride (SiN), silicon oxynitride (SiON), titanium nitride (TiN), tantalum nitride (TaN), or aluminum nitride (AlN), a combination thereof, or the like. Filling with metal may comprise deposition followed by planarization to remove excess metal. The deposition process may be PVD, CVD, ALD, electroplating, electroless plating, the like, or any other suitable process. Planarization may be chemical mechanical polishing (CMP) or the like.

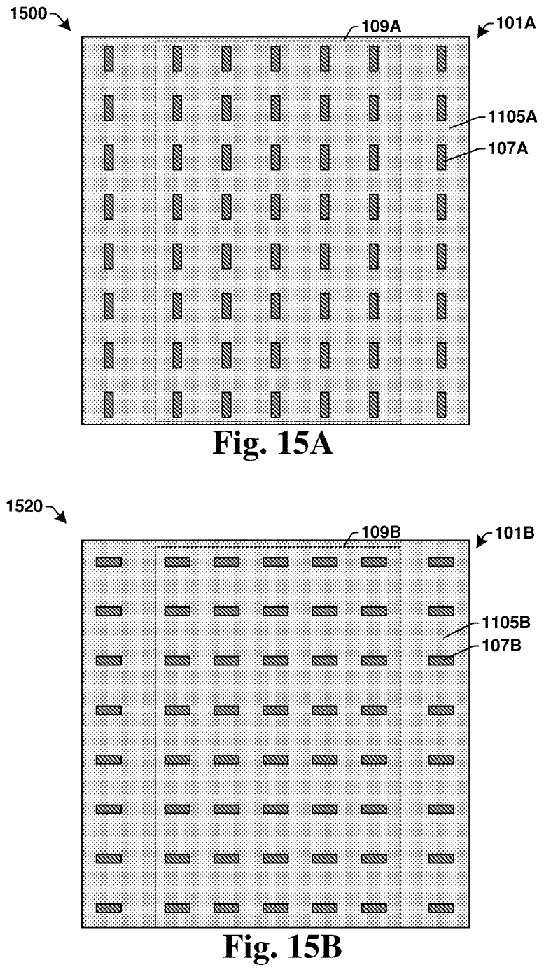

As shown by the cross-sectional view 1400 of FIG. 14, the second IC device 101B may be flipped over and aligned with the first IC device 101A so that bonding pads 107B on the second IC device 101B are aligned crosswise to corresponding bonding pads 107A on the first IC device 101A. The alignment of the bonding pads 107A and 107B is further illustrated by FIGS. 15A and 15B. FIG. 15A illustrates a plan view 1500 of the first IC device 101A taken along the line 15A-15A′ of FIG. 14. FIG. 15B illustrates a plan view 1520 of the second IC device 101B taken along the line 15B-15B′ of FIG. 14.

FIGS. 15A and 15B show rectangular areas, however, the first IC device 101A or the second IC device 101B may be circular and have far greater numbers of bonding pads than are shown. In some embodiments, the first IC device 101A and the second IC device 101B are wafers. In some embodiments, one of the first IC device 101A and the second IC device 101B is a wafer and the other is a chip. In some embodiments, both of the first IC device 101A and the second IC device 101B are chips. In some embodiments, the first IC device 101A or the second IC device 101B is a wafer that is at least about 200 mm in diameter. In some embodiments, the first IC device 101A or the second IC device 101B is a wafer that is at least about 300 mm in diameter. In some embodiments, the first IC device 101A or the second IC device 101B is a wafer that is at least about 450 mm in diameter. The greater the wafer size, the greater the variability in alignment among the bonding pads.

An alignment accuracy may be associated with the alignment process. The alignment accuracy may relate to an uncertainty in aligning any particular pair of bonding pads 107A and 107B due to a process constraint. Alternatively, the alignment accuracy may reflect variations in the relative positioning of the bonding pads 107A on the first IC device 101A and the bonding pads 107B on the second IC device 101B that prevents all the bonding pads 107A from being simultaneously perfectly aligned with corresponding bonding pads 107A. In some embodiments, the alignment accuracy is no better than about 45% the square root of the product of L₁ and W₁. In some embodiments, the alignment accuracy is no better than about 70% the square root of the product of L₁ and W₁. In some embodiments, the alignment accuracy is no better than about 10% a pitch of the bonding pads 107A in the array 109A. In some embodiments, the alignment accuracy is no better than about 25% a pitch of the bonding pads 107A in the array 109A. Increases in bonding area uniformity provided by oblong, crosswise bonding pads in accordance with the present disclosure are pronounced when the alignment accuracy is in these ranges.

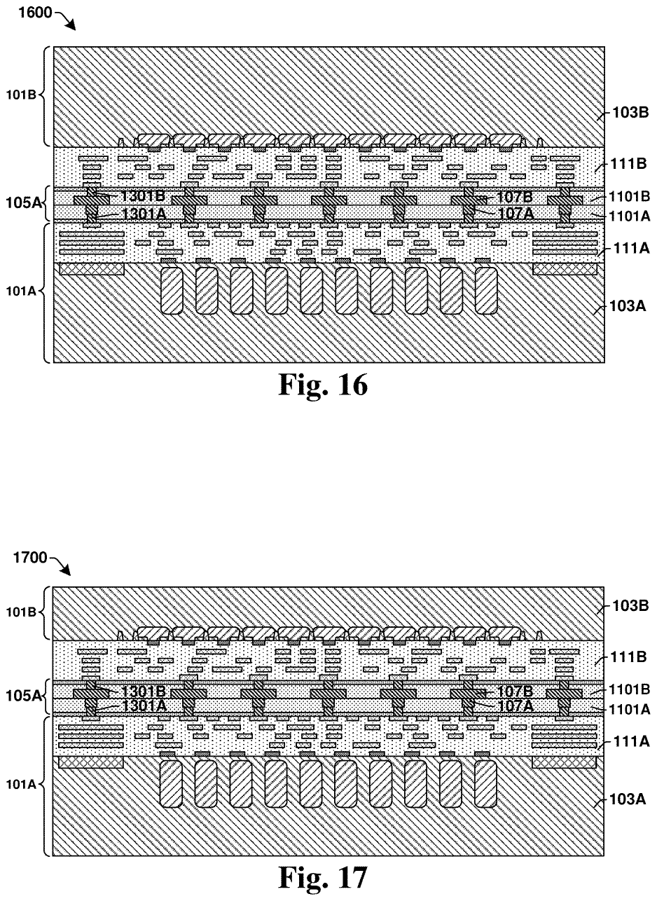

As shown by the cross-sectional view 16 of FIG. 16, the first IC device 101A and the second IC device 101B are joined and held together by forming the first bonding structure 105A. The first bonding structure 105A may include bonding between the dielectric bonding structure 1101A and the dielectric bonding structure 1101B as well as bonds between the bonding pads 107A and the bonding pad 107B. The bonding process may include the application of pressure and or annealing. Annealing may comprise heating to a temperature in the range from about 100 °C to about 500 °C. In some embodiments, the bonding process is carried out in an inert atmosphere.

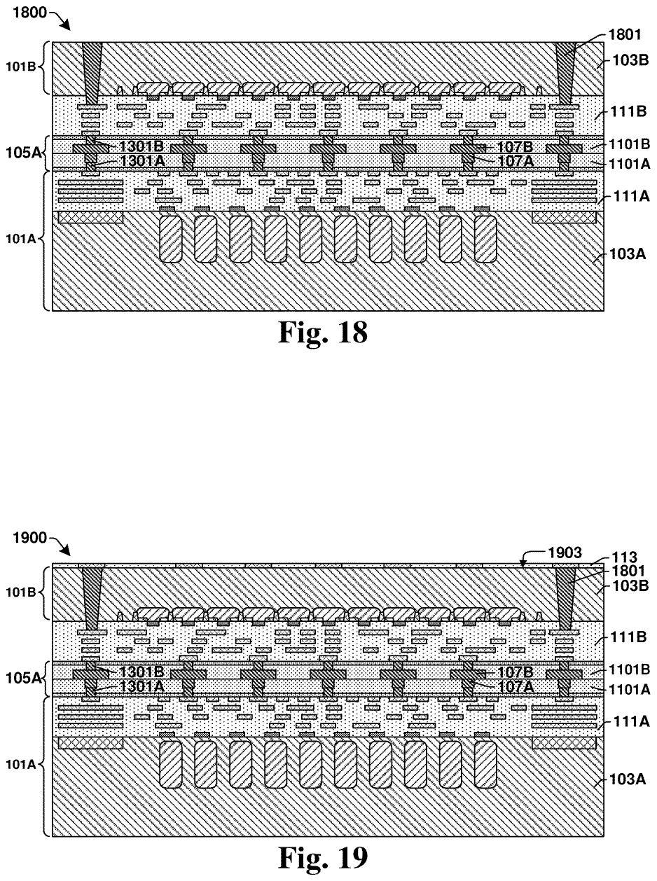

As shown by the cross-sectional view 17 of FIG. 17, the substrate 103B of the second IC device 101B may be thinned. The thinning process may comprise polishing or the like. In some embodiments, the substrate 103B is thinned to about 50 μm or less. In some embodiments, the substrate 103B is thinned to about 10 μm or less. As shown by the cross-sectional view 18 of FIG. 18, through substrate vias (TSVs) 1801 may then be formed. The TSVs 1801 may make connections with the metal interconnect 111B. As shown by the cross-sectional view 19 of FIG. 19, a redistribution layer 113 may be formed to route connections from the TSVs 1801 on the back side 1903 of the second IC device 101B.

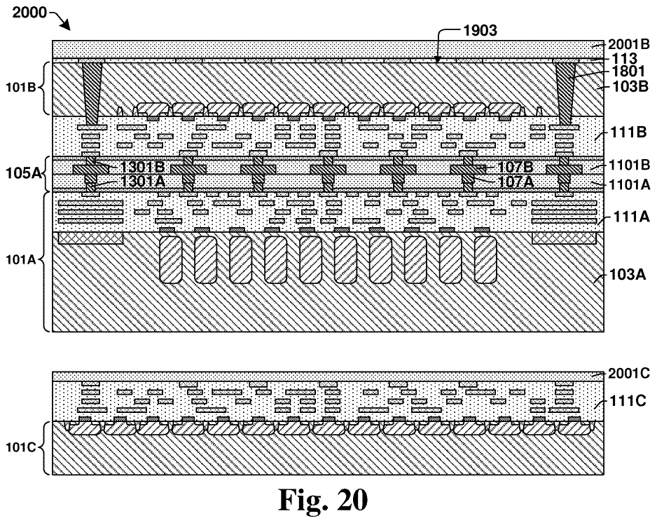

As shown by the cross-sectional view 2000 of FIG. 20, a dielectric bonding structure 2001B may be formed over the redistribution layer 113 of the second IC device 101B and a dielectric bonding structure 2001C may be formed over the third IC device 101C. Optionally the redistribution layer 113 is omitted and the dielectric bonding structure 2001B is formed directly on the back side 1903. The dielectric bonding structures 2001B and 2001C may be like the dielectric bonding structures 1101B and 1101C (see FIG. 11). In some embodiments, the dielectric bonding structure 2001B has the same composition as the dielectric bonding structure 2001C. In some embodiments, the dielectric bonding structure 2001B has a distinct composition as the dielectric bonding structure 2001C. One or the other embodiment may facilitate adhesion depending on the compositions.

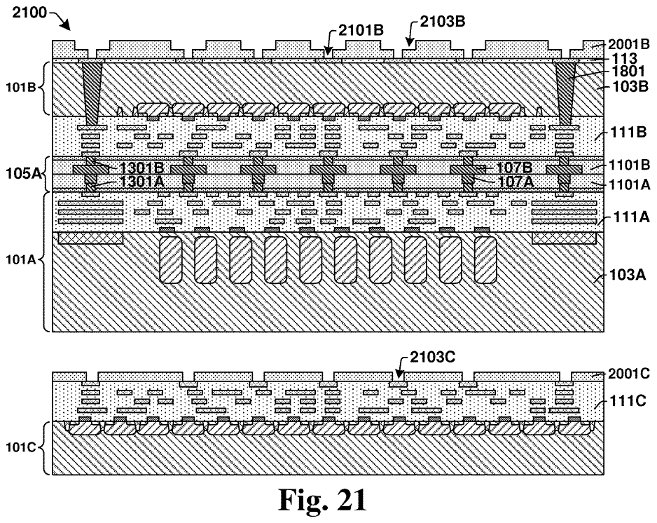

As shown by the cross-sectional view 2100 of FIG. 21, the dielectric bonding structures 2001B and 2001C are patterned. The patterning may be similar to the process described in connection with FIG. 12. Patterning provides the bonding pad openings 2103B and the via openings 2101B in the dielectric bonding structure 2001B. Patterning provides the bonding pad openings 2103C in the dielectric bonding structure 2001C. In this example, via openings are not formed in the dielectric bonding structure 2001C whereby the bonding pads may form directly on the metal interconnect 111C. This variation may be applied in connection with any of the dielectric bonding structures of the present disclosure.

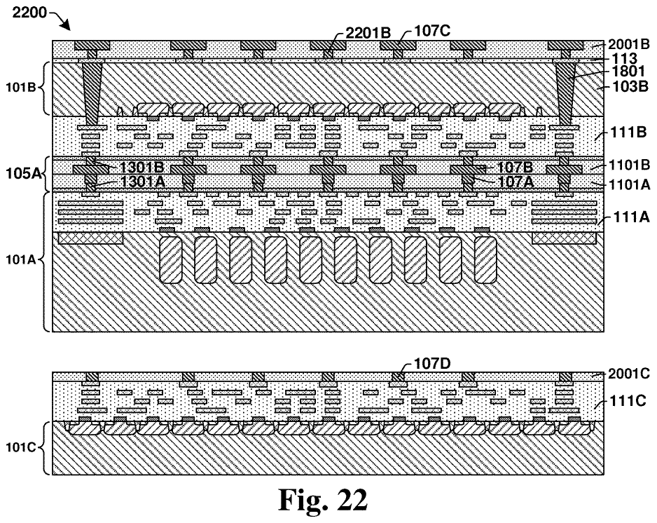

As shown by the cross-sectional view 2200 of FIG. 22, the via openings 2101B may be filled with metal or another conductor to form the vias 2201B, the bonding pad openings 2103B may be filled with metal to provide the bonding pads 107C, and in the bonding pad opening 2103C may be filled with metal to provide the bonding pads 107D. The process of filling these openings with metal may be the same as the on described in connection with FIG. 13.

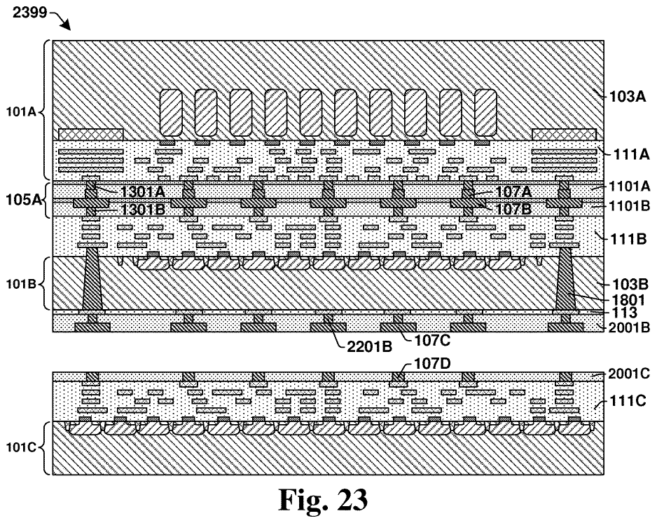

As shown by the cross-sectional view 2300 of FIG. 23, the first IC device 101A and the second IC device 101B may be flipped over and aligned with the third IC device 101C so that the bonding pads 107C on the second IC device 101B are aligned crosswise with corresponding bonding pads 107D on the third IC device 101C. The alignment of the bonding pads 107C and bonding pads 107D may be like the alignment illustrated by FIGS. 14, 15A, and 15B.

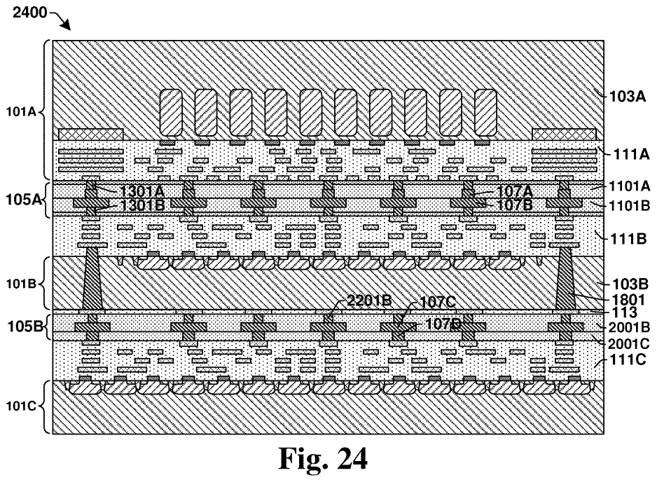

As shown by the cross-sectional view 2400 of FIG. 24, the second IC device 101B is bonded to the third IC device 101C by forming the second bonding structure 105B. The second bonding structure 105B may include bonding between the dielectric bonding structures 2001B and 2001C as well as bonds between the bonding pads 107C and 107D. The bonding process may include the application of pressure and or annealing.

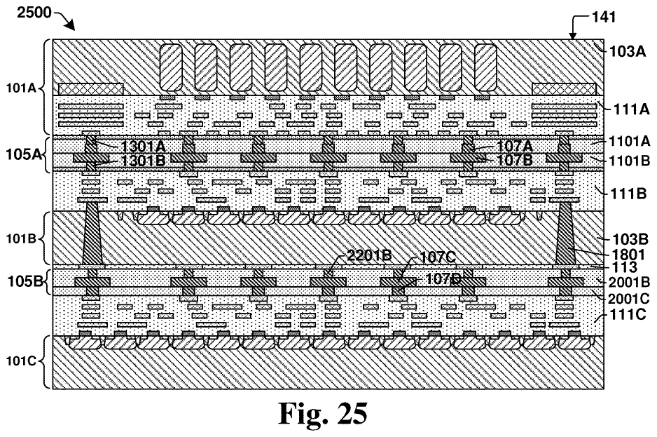

As shown by the cross-sectional view 2500 of FIG. 25, the substrate 103A may be thinned. The thinning process may comprise CMP or the like. In some embodiments, the first IC device 101A is thinned to about 50 μm or less. In some embodiments, the first IC device 101A is thinned to about 10 μm or less. Additional processing may then be carried out on the back side 141 of the first IC device 101A to form a structure like the one shown in FIG. 1A. This additional processing may include forming the isolation structure 135, a composite grid 131 including a back side metal grid 133, color filters 139, lenses 137, and contact pads 143.

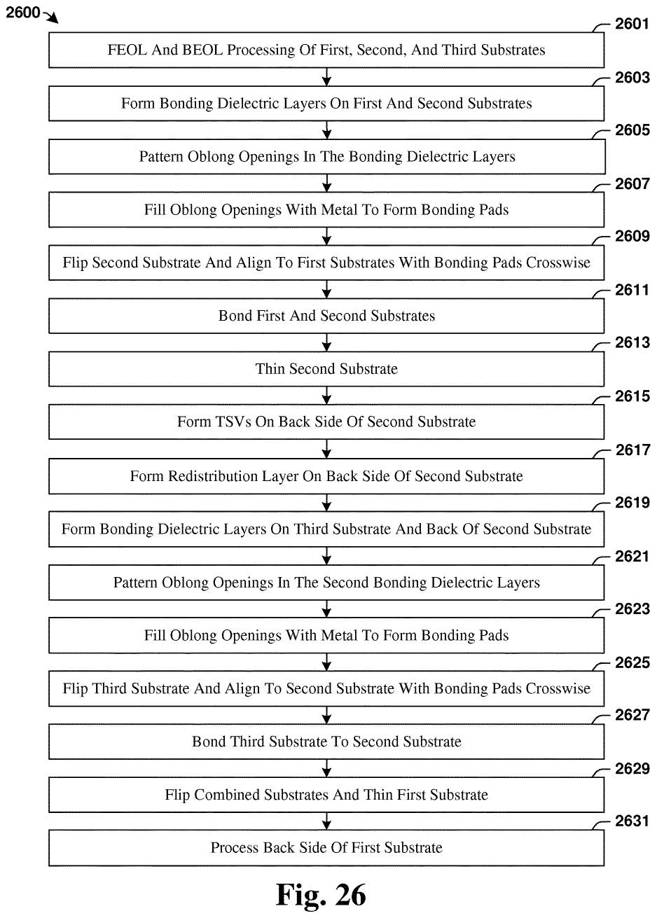

FIG. 26 presents a flow chart for a process 2600 that may be used to form an IC device with bonding structures in accordance with the present disclosure. The process 2600 includes steps for forming the 3D-IC device 100 of FIGS. 1A-1B but may be used to form other integrated circuit devices with fewer or additional features. While the process 2600 of FIG. 26 is illustrated and described herein as a series of acts or events, it will be appreciated that the illustrated ordering of such acts or events is not to be interpreted in a limiting sense. For example, some acts may occur in different orders and/or concurrently with other acts or events apart from those illustrated and/or described herein. Further, not all illustrated acts are required to implement one or more aspects or embodiments of the description herein, and one or more of the acts depicted herein may be carried out in one or more separate acts and/or phases.

The process 2600 may begin with act 2601, front-end-of-line (FEOL) processing and back-end-of-line processing on three substrates. The substrates can be any types of substrates. In some embodiments, one or more of the substrates comprises a semiconductor body, e.g., silicon (Si) or the like. In some embodiments, one or more of the substrates is a wafer. FEOL processing forms various structures in and on the semiconductor bodies. Those structures may include transistors, diodes, capacitors, memory cells, and the like. BEOL processing may form metal interconnect structures and redistribution layers.

Act 2603 is forming bonding dielectric layers on the first and second substrates. The cross-sectional view 1100 of FIG. 11 provides an example. Act 2605 is forming oblong opening in these bonding dielectric layers. The cross-sectional view 1200 of FIG. 12 provides an example. Act 2607 is filling the oblong openings with metal to form bonding pads. The cross-sectional view 1300 of FIG. 13 provides an example. Some of the bonding pads may be in arrays having a certain pitch. In some embodiments, the arrays are two-dimensional. The plan views 1500 and 1520 of FIGS. 15A and 15B provide an example.

Act 2609 is turning over the second substrate and aligning it with the first substrate so that the oblong bonding pads on the second substrate are opposite from and angled with respect to corresponding oblong bonding pads on the first substrate. In some embodiments, the oblong bonding pads on the second substrate are placed at right angles with corresponding oblong bonding pads on the first substrate. The cross-sectional view 1400 of FIG. 14 together with the plan views 1500 and 1520 of FIGS. 15A and 15B provide an example. Act 2611 is bonding the aligned substrates. The cross-sectional view 1600 of FIG. 16 provides an example.

Act 2613 is thinning the second substrate. The first substrate supports the second substrate during this thinning process. The cross-sectional view 1700 of FIG. 17 provides an example. Act 2615 is forming TSVs in the back side of the second substrate. The cross-sectional view 1800 of FIG. 18 provides an example. Act 2617 is forming a redistribution layer with connections to the TSV on the back side of the second substrate. The cross-sectional view 1900 of FIG. 19 provides an example.

Act 2619 is forming bonding dielectric layers on the third substrate and on the back side of the second substrate. The cross-sectional view 2000 of FIG. 20 provides an example. Act 2621 is forming oblong opening in these bonding dielectric layers. The cross-sectional view 2100 of FIG. 21 provides an example. Act 2623 is filling these oblong openings with metal to form bonding pads. The cross-sectional view 2200 of FIG. 22 provides an example.

Act 2625 is turning over the third substrate and aligning it with the first substrate so that the oblong bonding pads on the third substrate are opposite from and angled with respect to the oblong bonding pads on the back side of the second substrate. The cross-sectional view 2300 of FIG. 23 provides an example. Act 2627 is bonding the second and third substrates. The cross-sectional view 2400 of FIG. 24 provides an example.

Act 2629 is flipping over the combined substrates and thinning the first substrate. The cross-sectional view 2500 of FIG. 25 provides an example. Act 2631 is processing that may be carried out on the back side of the first substrate after thinning. This may include one or more of forming a photodiode isolation grid, forming a back side metal grid, forming color filters, forming lenses, forming contact pads, and the like. The 3D-IC device 100 of FIGS. 1A-1B provides an example of the type of structure that may be formed.

Some aspects of the present disclosure relate to a 3D-IC device that includes a first bonding pad on a first substrate and a second bonding pad on a second substrate. The first bonding pad is bonded to the second bonding pad at an interface between the first substrate and the second substrate. The first bonding pad is wider than the second bonding pad in a first cross-section that is perpendicular to the interface. The second bonding pad is wider than the first bonding pad in a second cross-section that is perpendicular to the interface and to the first cross-section. In some embodiments, the first bonding pad and the second bonding pad have equal lengths and widths. In some embodiments, the first bonding pad has a rectangular surface, has a first width, and has a first length that is greater than the first width, the second bonding pad has a rectangular surface, has a second width, and has a second length that is greater than the second width, and the first length lays across the second length. In some embodiments, the first and second bonding pads have elliptical surfaces and the major axis of the second bonding pad lays across the major axis of the first bonding pad.

In some embodiments, the first bonding pad has a first line of symmetry that is a longest line of symmetry for the first bonding pad, the second bonding pad has a second line of symmetry that is a longest line of symmetry for the second bonding pad, and the first line of symmetry is nearer to perpendicular than to parallel with respect to the second line of symmetry. In some embodiments, the first line of symmetry is at a right angle to the second line of symmetry. In some embodiments, the shapes and orientations of the first bonding pad and the second bonding pad limit an area of contact between them to two thirds or less an area of the smallest of the first bonding pad and the second bonding pad. In some embodiments, an area of contact between the first bonding pad and the second bonding pad has a derivative of zero with respect to linear displacement in any direction in a plane of the interface.

In some embodiments the first bonding pad is one of a plurality of first bonding pads in a first array, the second bonding pad is one of a plurality of second bonding pads in a second array, and the first bonding pads in the first array are bonded to respective second bonding pads in the second array. In some embodiments, the first bonding pad is coupled to a floating diffusion region of a photodetector. In some embodiments the two wires that are closest to the bonding pad among those in the metallization layer immediately below the first bonding pad but not coupled to the first bonding pad run parallel to a length of the first bonding pad.

Some aspects of the present disclosure relate to an integrated circuit device that includes a bonding structure comprising first bonding pads on a first substrate and second bonding pads on a second substrate. The first bonding pads are joined to the second bonding pads. The first bonding pads and the second bonding pads are oblong and angled relative to one another so as to reduce a rate of bonding area variation with respect to a variation in alignment between the first substrate and the second substrate. In some embodiments, the first bonding pads are oriented at right angles to the second bonding pads. In some embodiments, the rate of bonding area variation with respect to the variation in alignment between the first substrate and the second substrate is zero.

Some aspects of the present disclosure relate to a method that includes forming a first bonding pad having a first oblong surface on a first substrate, forming a second bonding pad having a second oblong surface on a second substrate, aligning the first substrate and the second substrate so that the first oblong surface lays across the second oblong surface, and forming a bond between the first bonding pad and the second bonding pad. In some embodiments, the first bonding pad is one in a first array of first bonding pads have first oblong surfaces, the second bonding pad is one in a second array of second bonding pads have second oblong surfaces and forming the bond between the first bonding pad and the second bonding pad forms bonds between first bonding pads in the first array and respective second bonding pads in the second array. In some embodiments, the first array and the second array are two-dimensional arrays. In some embodiments, forming the bond between the first bonding pad and the second bonding pad comprises annealing. In some embodiments, the first oblong surface is rectangular. In some embodiments, the first oblong surface is elliptical.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a first bonding pad on a first integrated circuit (IC) device; and
a second bonding pad on a second IC device;
wherein the first bonding pad is bonded to the second bonding pad at an interface between the first IC device and the second IC device;
the first bonding pad is wider than the second bonding pad in a first cross-section that is perpendicular to the interface; and
the second bonding pad is wider than the first bonding pad in a second cross-section that is perpendicular to the interface and to the first cross-section.

2. The device of claim 1, wherein the first bonding pad and the second bonding pad have equal lengths and widths.

3. The device of claim 1, wherein:
the first bonding pad has a rectangular surface with a first width and a first length that is greater than the first width;
the second bonding pad has a rectangular surface with a second width and a second length that is greater than the second width; and
the first length lays across the second length.

4. The device of claim 1, wherein:
the first bonding pad has an elliptical surface with a first major axis and a first minor axis;
the second bonding pad has an elliptical surface with a second major axis and a second minor axis; and
the first major axis lays across the second major axis.

5. The device of claim 1, wherein:
the first bonding pad has a first line of symmetry that is a longest line of symmetry for the first bonding pad;
the second bonding pad has a second line of symmetry that is a longest line of symmetry for the second bonding pad; and
the first line of symmetry is nearer to perpendicular than to parallel with respect to the second line of symmetry.

6. The device of claim 5, wherein the first line of symmetry is at a right angle to the second line of symmetry.

7. The device of claim 1, wherein shapes and orientations of the first bonding pad and the second bonding pad limit an area of contact between them to two thirds or less an area of the smallest of the first bonding pad and the second bonding pad.

8. The device of claim 1, wherein an area of contact between the first bonding pad and the second bonding pad has a derivative of zero with respect to linear displacement in any direction in a plane of the interface.

9. The device of claim 1, wherein:
the first bonding pad is one of a plurality of first bonding pads in a first array;
the second bonding pad is one of a plurality of second bonding pads in a second array; and
the first bonding pads in the first array are bonded to respective second bonding pads in the second array.

10. The device of claim 1, wherein the first bonding pad is coupled to a floating diffusion region of a photodetector.

11. The device of claim 1, further comprising:
two wires within a metallization layer immediately below the first bonding pad on the first IC device
wherein the two wires are closest to the first bonding pad among those that are in the metallization layer but not coupled to the first bonding pad; and
the two wires run parallel to a length of the first bonding pad.

12. An integrated circuit device, comprising:
a bonding structure comprising first bonding pads on a first substrate and second bonding pads on a second substrate, wherein the first bonding pads are joined to the second bonding pads;
wherein the first bonding pads and the second bonding pads are oblong and angled relative to one another so as to reduce a rate of bonding area variation with respect to a variation in alignment between the first substrate and the second substrate.

13. The integrated circuit device of claim 12, wherein the first bonding pads are oriented at right angles to the second bonding pads.

14. The integrated circuit device of claim 12, wherein the rate of bonding area variation with respect to the variation in alignment between the first substrate and the second substrate is zero.

15. A method comprising:
forming a first bonding pad having a first oblong surface on a first substrate;
forming a second bonding pad having a second oblong surface on a second substrate;
aligning the first substrate and the second substrate so that the first oblong surface lays across the second oblong surface; and
forming a bond between the first bonding pad and the second bonding pad.

16. The method of claim 15, wherein:
the first bonding pad is one in a first array of first bonding pads have first oblong surfaces;
the second bonding pad is one in a second array of second bonding pads have second oblong surfaces; and
forming the bond between the first bonding pad and the second bonding pad forms bonds between first bonding pads in the first array and respective second bonding pads in the second array.

17. The method of claim 16, wherein the first array and the second array are two-dimensional arrays.

18. The method of claim 16, wherein forming the bond between the first bonding pad and the second bonding pad comprises annealing.

19. The method of claim 16, wherein the first oblong surfaces are rectangular.

20. The method of claim 16, wherein the first oblong surfaces are elliptical.
